(19) United States
(12) Patent Application Publication
(10) Pub. No.: US 2018/0294135 A1
(43) Pub. Date: Oct. 11, 2018

(54) Device for the Extraction of Electrical Charge Carriers from a Charge Carrier Generation Space and Method for Operating Such a Device

(71) Applicant: Meyer Burger (Germany) AG, Hohenstein-Ernstthal (DE)

(72) Inventors: Joachim Mai, Nobitz (DE); Alfonz Luca, Chemnitz (DE); Margit Sarstedt, Frankfurt am Main (DE)

(21) Appl. No.: 15/542,445

(22) PCT Filed: Jan. 6, 2016
(86) PCT No.: PCT/EP2016/050121

§ 371 Date: Jul. 10, 2017

(30) Foreign Application Priority Data
Jan. 9, 2015 (EP) 15150613.6

(51) Int. Cl. H01J 37/08

(52) U.S. Cl. CPC H01J 37/08; H01J 2237/0653; H01J 2237/083; H01J 2237/0656

(57) ABSTRACT

The invention relates to a device for extracting electrical charge carriers from a charge carrier generation chamber with at least one electrode arrangement for extracting charge carriers, wherein the at least one electrode arrangement has at least a first grid electrode and a second grid electrode with corresponding openings. The first and the second grid electrode each contain at least one first electrically conductive grid electrode region, wherein the at least one first grid electrode region of the first grid electrode is configured in a first layer and the at least one first grid electrode region of the second grid electrode is configured in a second layer. The first layer and the second layer are arranged one after the other within the electrode arrangement in the particle emission direction and are spaced from one another by a first distance along the particle emission direction, wherein the at least one first grid electrode region of the first grid electrode forms a first electrically conductive layer portion in the first layer. In addition, a second electrically conductive layer portion, which is electrically insulated from the first layer portion, is configured in the first layer. The second layer portion is formed by at least one second electrically conductive grid electrode region of the first grid electrode or of the second grid electrode, and the second layer portion is electrically conductively connected to the at least one first grid electrode region of the second grid electrode. The device according to the invention for extracting charge carriers thus represents an electrically switchable extraction grid electrode arrangement by the aid of which the beam characteristics of a particle beam of extracted charge carriers can be changed.

### CROSS REFERENCE TO RELATED APPLICATIONS

This application is the U.S. national stage of International Application No. PCT/EP2016/050121, filed on 2016-01-06. The international application claims the priority of EP 15150613.6 filed on 2015-01-09; all applications are incorporated by reference herein in their entirety.

### BACKGROUND

The invention relates to a device for extracting electrical charge carriers from a charge carrier generation chamber which allows a change in the shape of the total beam of particles extracted with the aid of the device, and a method for operating such a device. In addition, the invention relates to a method for processing the surface of a substrate using one or more total beams of particles generated with at least one such device.

Directed particle beams from electrical charge carriers, for example, ion beams or electron beams, are generated in a particle beam source by the extraction of electrical charge carriers, i.e., ions or electrons, from a charge carrier generation chamber, for example, a plasma, wherein the particles move directed in the form of a beam in a space in a particle emission direction after leaving the particle beam source. For this purpose, in particular for the generation of broad beams with a beam width of up to 1 m, one or more devices for extracting electrical charge carriers are used, each of which consists of one or more grid electrodes, and extracts and possibly accelerates the particles from the charge carrier generation chamber and and aligns the individual particle partial beams arising therefrom with one another. A grid electrode in this case is understood to mean a mechanical (physical or material) composite of a plurality, i.e., of at least two, of openings through which the charge carriers can pass. In other words: A grid electrode is a (generally) flat-shaped component, the lateral dimensions of which are many times greater than its thickness, i.e., its extent in the particle emission direction, and which has a plurality of openings which extend in the thickness direction over the entire thickness of the component and allow passage of charge carriers through the component. The grid electrode has, at least in some regions, an electrically conductive material which can be charged with a potential so that the charge carriers can be extracted and accelerated, or the partial beam(s) can be blocked. The electrically conductive grid electrode regions can be physically and electrically conductively connected to each other. This is the case, for example, for a grid electrode configured entirely from an electrically conductive material. However, the individual electrically conductive grid electrode regions can also be electrically insulated from one another, for example, by an electrically insulating material arranged between them. In a device for extracting electrical charge carriers, a plurality of grid electrodes can be arranged one after the other in the particle emission direction in layers spaced apart from each other, wherein the openings of the individual grid electrodes correspond to one another so that charge carriers can pass through the openings of the grid electrodes as particle beams in case of a corresponding potential charging of the individual grid electrodes or grid electrode regions. Often, at least three grid electrodes are used, which are referred to as plasma, screen or beam grid electrodes, as acceleration grid electrodes, and as ground grid electrodes according to their function. However, further electrodes can also be arranged in the device for extracting electrical charge carriers in order, for example, to influence the generated total beam of particles with respect to its emission direction.

Particle beams are used, for example, in ion beam or electron beam processing systems, among other things, for processing surfaces of a substrate. The topography of the surface or other physical or chemical properties of the surface, such as, for example, hygroscopic properties, can thereby be altered by the particles impinging the surface. In doing so, both the achievable resolution, i.e., the minimum processed area, as well as the quality of the processing, strongly depend on the beam width of the total beam used. In general, better processing results are achieved with a small beam width. For example, small thickness differences within a layer located on the surface of the substrate can be more accurately leveled out with a total beam having a small beam width than with a total beam having a large beam width. This, however, is accompanied by a longer processing time for a substrate with a given surface.

To solve this problem, various possibilities for shaping an ion beam are known from the prior art in which the width or shape of the ion beam can be adapted to the necessary processing quality or processing resolution. This comprises, on the one hand, the use of various apertures or grid electrode arrangements with which a part of the ion beam can be suppressed or not even extracted. In order to adjust the width of the ion beam, the aperture or the grid(s) or possibly the entire ion beam source is exchanged, but this leads to contamination by the mechanical movement or leads to long breaking-in times of the newly installed ion beam source.

Furthermore, the targeted electrical control of individual lateral regions of the grid electrode arrangement is known. For example, U.S. Pat. No. 4,523,971 A describes that each grid opening of a grid electrode can be separately charged with a potential such that the corresponding partial ion beam is passed through or blocked. However, in addition to a high interconnection and addressing complexity, this leads to a low ion current density, since certain minimum distances between the individual electrical drives of the grid electrode openings must be maintained, which results in large distances between the individual openings. U.S. Pat. No. 4,758,304 A, discloses a grid electrode in which concentric circular segments are configured in a conductive layer, wherein the circular segments are broken at a common point and are charged with a potential by means of conductor paths which are arranged in this break.

A disadvantage of these devices is that electrical leads must be led out of the interior of a grid electrode to the outside to a voltage supply. This type of potential charging presents a great challenge for the present potential differences of up to 1500 V between the various grid electrodes or grid electrode regions as well as temperatures of up to 300° C., to which the grid electrodes are exposed during the operation of the particle beam source.

Additional switching grids with line-shaped segments are known from DE 10 2004 002 508 B4, in which this disadvantage is eliminated. Here, it is possible to contact each line-shaped segment from the outside and individually electrically control it. However, the shaping of an ion beam with an unsealed cross-sectional profile requires the control of at least two of these segments.

### SUMMARY

The invention relates to a device for extracting electrical charge carriers from a charge carrier generation chamber with at least one electrode arrangement for extracting charge carriers, wherein the at least one electrode arrangement has at least a first grid electrode and a second grid electrode with corresponding openings. The first and the second grid electrode each contain at least one first electrically conductive grid electrode region, wherein the at least one first grid electrode region of the first grid electrode is configured in a first layer and the at least one first grid electrode region of the second grid electrode is configured in a second layer. The first layer and the second layer are arranged one after the other within the electrode arrangement in the particle emission direction and are spaced from one another by a first distance along the particle emission direction, wherein the at least one first grid electrode region of the first grid electrode forms a first electrically conductive layer portion in the first layer. In addition, a second electrically conductive layer portion, which is electrically insulated from the first layer portion, is configured in the first layer. The second layer portion is formed by at least one second electrically conductive grid electrode region of the first grid electrode or of the second grid electrode, and the second layer portion is electrically conductively connected to the at least one first grid electrode region of the second grid electrode. The device according to the invention for extracting charge carriers thus represents an electrically switchable extraction grid electrode arrangement by the aid of which the beam characteristics of a particle beam of extracted charge carriers can be changed.

### DETAILED DESCRIPTION

It is therefore the object of the present invention to overcome the disadvantages of the prior art and to provide a simple possibility for shaping a total beam of particles with the aid of electrically switchable grid electrodes.

This object is achieved by the device for extracting electrical charge carriers and the method for operating the device for extracting electrical charge carriers according to the independent claims. Moreover, a method for processing a surface of a substrate using such a device for extracting electrical charge carriers is claimed. Advantageous further developments can be found in the subclaims.

A device according to the invention for the extraction of electrical charge carriers from a charge carrier generation chamber comprises at least one electrode arrangement which has at least a first grid electrode and a second grid electrode with corresponding openings which each contain at least one first grid electrode region that is configured electrically conductive. The openings are used for the passage of the charge carriers through the respective grid electrode in the particle emission direction and have lateral extensions and a predetermined circumferential geometry, for example, a round, elliptical, angular or irregular circumferential geometry. In this case, the lateral extensions and/or the circumferential geometries of mutually corresponding openings in the first and the second grid electrode can deviate slightly from each other. In the context of the application, “corresponding openings” in a first grid electrode and a second grid electrode are understood to mean openings which are arranged in different layers and which are suitable to allow passage of charge carriers as particle beams through the corresponding openings of the various grid electrodes, if the individual grid electrodes or grid electrode regions are charged with a corresponding potential.

According to the invention, at least the at least one first grid electrode region of the first grid electrode is configured in a first layer, while the at least one first grid electrode region of the second grid electrode is configured in a second layer. The first layer and the second layer each delineate a surface within the electrode arrangement, i.e., in the space of the device for extracting electrical charge carriers, in which the at least two grid electrodes are arranged, wherein the first layer and the second layer are arranged one after the other in the particle emission direction and are always spaced apart by a first distance along the particle emission direction. The first layer and the second layer can delineate planar or uniformly or non-uniformly curved surfaces which can have arbitrary circumferential geometries in a projection of the layer in the particle emission direction. For example, the layers can be configured in such a way that the individual partial beams passing through the openings in the grid electrodes are focused, aligned parallel to one another or defocused. In addition, the arrangement of the second layer is possible before or after the first layer along the particle emission direction.

The at least one first grid electrode region of the first grid electrode forms a first electrically conductive layer portion of the first layer. In addition, a second electrically conductive layer portion, which is formed by at least one second electrically conductive grid electrode region of the first grid electrode or of the second grid electrode, is configured in the first layer. The first layer portion and the second layer portion are electrically insulated from one another and each extend over the entire thickness of the first layer, i.e., over the entire extension of the layer in the particle emission direction. The second layer portion is electrically conductively connected to the at least one first grid electrode region of the second grid electrode. In both the first layer portion and the second layer portion, the above-described openings are configured in the respective grid electrode or in the respective grid electrode region, wherein the openings are suitable for the passage of charge carriers.

Since the first layer portion is electrically insulated from the second layer portion, they can be charged with different or equal potentials. According to the invention, this is applied to the second layer portion via the at least one first grid electrode region of the second grid electrode. Thus, a potential feed of the second layer portion electrically insulated from the first layer portion is dispensed with within the first layer.

The device according to the invention for the extraction of charge carriers thus represents an electrically switchable extraction grid electrode arrangement by the aid of which the beam characteristics of a particle beam can be changed.

Since the first grid electrode regions of the first grid electrode and of the second grid electrode are preferably arranged within the respective grid electrode so as to adjoin the outer lateral circumference of the respective grid electrode, a second layer portion, which is spaced apart from the outer lateral circumference of the first grid electrode and has a different electrical potential from the first layer portion, is thus possible. In this case, neither electrical leads from the interior of the first grid electrode to the outer circumference of the first grid electrode are required for the application of the potential, nor is an elaborate control of one or more segments of a grid electrode necessary.

In a first embodiment, the first grid electrode comprises only the at least one first grid electrode region, while the second grid electrode has at least one second grid electrode region which forms the second layer portion of the first layer. In other words: The first grid electrode is configured in such a way that it does not completely map the first layer but has at least one recess. This recess can be adjacent to the lateral circumference of the first grid electrode, i.e., can be configured on the edge of the first grid electrode, or be spaced therefrom, i.e., be configured in the interior of the first grid electrode. The at least one second grid electrode region of the second grid electrode is arranged in the recess and thus at least partially in the first layer. The at least one second grid electrode region of the second grid electrode is physically and electrically conductively connected to the at least one first grid electrode region of the second grid electrode and is preferably configured as one piece with it.

Preferably, the at least one second grid electrode region of the second grid electrode is configured so thick that a first surface of the at least one second grid electrode region of the second grid electrode is in the first layer, and a second surface of the at least one second grid electrode region of the second grid electrode, which is opposite to the first surface, is in the second layer. Thus, the second grid electrode is configured substantially thicker in the at least one second grid electrode region than the at least one first grid electrode region of the second grid electrode. The second grid electrode thus “projects” into the first layer or into the first grid electrode.

In another preferred design of the first embodiment, the at least one second grid electrode region of the second grid electrode has the same thickness as the at least one first grid electrode region of the second grid electrode. Thus, the second grid electrode is configured equally thick in the first and second grid electrode regions and is shaped such that the at least one second grid electrode region is arranged in the first layer. The second grid electrode can have a larger or smaller thickness in the transition regions between the at least one first grid electrode region and the at least one second grid electrode region. This means that the second grid electrode is “put over into” the first layer or into the first grid electrode, respectively.

Preferably, the second grid electrode of the first two designs of the first embodiment is configured in such a way that the transitions between the at least one first grid electrode region of the second grid electrode and the at least one second grid electrode region of the second grid electrode runs continuously on both surfaces of the second grid electrode. For this purpose, the transitions can, for example, be configured rounded and/or inclined. Thus, inhomogeneities within the electric field between the second grid electrode and arrangements with a different potential, e.g., the first grid electrode, another grid electrode, or the charge carrier generation chamber, are minimized.

In a further preferred design of the first embodiment, the at least one first grid electrode region of the second grid electrode completely maps the second layer, while the at least one second grid electrode region of the second grid electrode is spaced at least in some lateral sections of the second grid electrode region from the at least one first grid electrode region of the second grid electrode. In other words: The second grid electrode does not form a closed structure, but rather consists of two partial parts, which are connected to one another in an electrically conductive manner in some lateral sections of the at least one second grid electrode region. The at least one second grid electrode region of the second grid electrode is configured as a physically independent grid electrode which is, however, electrically connected, for example, via electrically conductive spacers, to the at least one first grid electrode region of the second grid electrode, which completely maps the second layer.

In a second embodiment, the first grid electrode further comprises at least one second grid electrode region which forms the second layer portion of the first layer. Thus, the first grid electrode is physically configured in one piece and completely maps the first layer, wherein however the at least one first grid electrode region is electrically insulated from the at least one second grid electrode region. The second grid electrode has at least a first grid electrode region, which is configured in the second layer and is connected in an electrically conductive manner to the at least one second grid electrode region of the first grid electrode. Preferably, the second grid electrode is also physically configured in one piece and completely maps the second layer. In other words: The first grid electrode and the second grid electrode are configured in such a way that they completely map the first layer or the second layer, respectively, and are electrically conductively connected to one another in the region of the second layer portion.

Also possible is an electrode arrangement which comprises a plurality of lateral regions, wherein different embodiments are configured in different regions.

Preferably, the openings for the charge carrier passage in at least one second grid electrode region of the first grid electrode or of the second grid electrode are identical to or different from the openings for the charge carrier passage in at least one first grid electrode region of the second grid electrode with respect to its lateral extension and/or its circumferential geometry. With the adaptation of the lateral extension and/or the circumferential geometry of the openings in the second grid electrode region, different influencing of the charge carriers due to the electric field as a result of the different spacing between the second grid electrode regions and an arrangement with a different potential with respect to the distance between the first grid electrode regions of the second grid electrode and the same arrangement with a different potential or due to the thickness difference between the first grid electrode regions and the second grid electrode regions of the second grid electrode can be reduced.

In both embodiments, the second layer portion of the first layer may be configured by a coherent second grid electrode region of the first or of the second grid electrode.

In another case, the second layer portion of the first layer may also be configured by a plurality of mutually spaced second grid electrode regions of the first or second grid electrode. In this case, the second grid electrode regions can have the same or different circumferential geometries, i.e., shapes in the projection of the grid electrode region in the particle emission direction. For example, round, ellipsoidal, three-, four- or multi-sided shapes or non-uniform shapes are possible. The second grid electrode regions may be distributed uniformly or non-uniformly over the lateral extension of the first layer. For example, they can be arranged uniformly with respect to a rotational axis or one or more intersecting lines of the first layer.

In addition, the at least one electrode arrangement preferably has at least one further, electrically conductive grid electrode provided with corresponding openings. Each of these further grid electrodes comprises at least a first grid electrode region in a further layer. The further layer may be arranged in front of or behind the second layer along the particle emission direction in the electrode space, wherein the further layer and the layer adjacent thereto, for example, the second layer, are spaced apart from each other by a further distance along the particle emission direction. The further layer delineates a surface congruent or similar to the first and the second layer.

A further grid electrode is preferably a ground grid electrode. However, other grid electrodes may also be present as further grid electrodes.

If the at least one electrode arrangement comprises at least one further grid electrode which is arranged adjacent to the second grid electrode on the side of the second grid electrode which is turned away from the first grid electrode, and the second grid electrode is configured such that the at least one second grid electrode region of the second grid electrode has the same thickness as the at least one first grid electrode region of the second grid electrode, then this further grid electrode preferably also has at least one second grid electrode region which is arranged in the second layer and is electrically conductively connected to the at least one first grid electrode region of the further grid electrode. In this case, the lateral arrangement of the at least one second grid electrode region of the further grid electrode within the second layer corresponds to the lateral arrangement of the at least one second grid electrode region of the second grid electrode within the first layer. Other grid electrodes which are adjacent to this further grid electrode can also have grid electrode regions which are arranged in different layers. In other words: Further grid electrodes can also be “put over” into the respective adjacent grid electrode or “extend” into it.

The said first and second grid electrode regions of the first grid electrode, of the second grid electrode or of a further grid electrode each have the described openings which correspond to the openings in other grid electrodes. In addition, one or more or all of the grid electrodes of the electrode arrangement may each have further regions in which no openings are configured. These regions are, for example, edge regions which are used to hold the respective grid electrode in the electrode arrangement and/or for the electrical contacting of the grid electrode regions of the respective grid electrode that are electrically conductively connected to this region.

In a particular embodiment, the device for extracting electrical charge carriers has a plurality of electrode arrangements for extracting charge carriers, wherein one or more of the electrode arrangements are arranged side by side in a first direction along the lateral extension of the device for extracting electrical charge carriers and at most two electrode arrangements arranged side by side in a second direction along the lateral extension of the device for extracting electrical charge carriers so that the electrode arrangements cover almost the entire lateral extension of the device for extracting electrical charge carriers. Only edge regions of the device for extracting electrical charge carriers and/or regions between adjacent electrode arrangements can be excluded from this. Since the several electrode arrangements are arranged at most in an n×2 matrix, all electrode arrangements can be contacted from the outside for charging with defined potentials. Thus, no electrical leads are necessary in the interior of the lateral extension of the device for extracting electrical charge carriers, and the control of the individual electrode arrangements is simplified. The lateral extension of the device for extracting electrical charge carriers is the extension of the device for extracting electrical charge carriers in the surface in which the charge carriers can be extracted from a charge carrier generation chamber, for example, a plasma, by means of the at least one electrode arrangement. That is, the lateral extension is defined perpendicular to the particle emission direction. The plurality of electrode arrangements may have the same or different patterns of the second layer portions. The term pattern should be understood here to mean both the one or more circumferential geometries of the at least one second grid electrode region and the lateral arrangement of the at least one second grid electrode region in a specific electrode arrangement.

Preferably, one, several or all of the grid electrodes contained in the electrode arrangement is or are arranged detachable from a holder of the electrode arrangement or from one of the other grid electrodes. Thus, individual grid electrodes, which have, for example, a higher degree of wear due to thermal, mechanical or electrical stress, can be individually removed from the electrode arrangement and exchanged or replaced by new grid electrodes. If the first and the second grid electrode are exchanged and replaced by corresponding grid electrodes which have a different pattern, a new device for extracting electrical charge carriers can be created such that it allows a new, different beam characteristic of the particle beam that can be produced.

In a preferred embodiment, the at least one electrode arrangement in the particle emission direction successively comprises a plasma grid electrode, a switching grid electrode and an acceleration grid electrode, wherein the switching grid electrode is the first grid electrode and the plasma grid electrode or the acceleration grid electrode is the second grid electrode. Here, “successively” means only that said grid electrodes are arranged in the order mentioned. Further grid electrodes can be arranged between the switching grid electrode and the grid electrode which is not the second grid electrode.

In a method according to the invention for operating a device for extracting electrical charge carriers according to the invention with a plasma grid electrode, a switching grid electrode and an acceleration grid electrode, in which the switching grid electrode is the first grid electrode and the plasma grid electrode or the acceleration grid electrode is the second grid electrode, depending on a desired beam characteristic of the particle beam passing through one of the at least one electrode arrangement, each of the at least one electrode arrangement is controlled with the aid of a device for generating one or more electrical voltages as well as a switching device, so that the at least one first grid electrode region of the switching grid electrode of the specific electrode arrangement is charged with a first potential and the acceleration grid electrode of the specific electrode arrangement is charged with a second potential. The values of the first and second potentials are selected in the individual switching states of the device for extracting electrical charge carriers in such a way that they allow passage of the charge carriers through the corresponding grid electrode regions or block the corresponding grid electrode regions for the charge carrier passage and always refer to the potential value of the plasma grid electrode or of the charge carrier generation chamber. The values of the first and second potentials for a charge carrier passage are in this case always more negative than the potential of the plasma grid electrode for positive charge carriers and more positive than this for negative charge carriers. The values of the first and second potentials for blocking the charge carrier passage, on the other hand, are higher positive values than the potential of the plasma grid electrode or the charge carrier generation chamber for positive charge carriers, whereas for negative charge carriers these are higher negative values. The individual specific potential values for the switching grid electrode and the acceleration grid electrode therefore depend on the charge carrier type and polarity as well as on the specific configuration of the device for extracting electrical charge carriers and the charge carrier generation chamber.

In a first switching state, the first potential has a first value U₁₁ and the second potential has a second value U_{21,} both of which are suitable for enabling the passage of charge carriers through the corresponding grid electrode regions. In this case, the first value U₁₁ and the second value U₂₁ may be equal to or nearly equal to or substantially deviate from each other as long as the charge carrier passage is ensured. With this first switching state, the entire lateral extension of the electrode arrangement for extracting charge carriers is released, so that a total beam with a large lateral extension is generated.

In a second switching state, the first potential has a third value U₁₂ which prevents a charge carrier passage through the grid electrode regions of the switching grid electrode and of the acceleration grid electrode corresponding to the first layer portion and the second potential has a fourth value U₂₂ which allows the passage of charge carriers through the grid electrode regions in the switching grid electrode and in the acceleration grid electrode corresponding to the second layer portion. Thus, the first layer portion for extracting charge carriers is electrically hidden, whereby one or more partial beams each having a small lateral extension are generated.

In a third switching state, the first potential has a fifth value U₁₃ and the second potential has a sixth value U_{23,} which both prevent the charge carrier passage through the corresponding grid electrode regions. In this case, the fifth value U₁₃ and the sixth value U₂₃ can be equal, nearly the same or different. This prevents the extraction of charge carriers over the entire lateral extension of the electrode arrangement and no particle beam is generated.

The concrete values of the potentials are adapted to the respective configuration of the electrode arrangement and the respective switching state. Thus, for example, the third value U₁₂ and the fifth value U_{13,} which both prevent the charge carrier passage through the at least one first grid electrode region of the switching grid electrode, can be equal, almost equal or different. The same applies to the second value U₂₁ and the fourth value U_{22,} which both permit the charge carrier passage through the grid electrode regions of the acceleration grid electrode.

Preferably, the first potential and/or the second potential are charged in a pulsed manner. The pulse lengths and/or the pulse ratios of the respective potentials can be the same or different from one another in this case. A temporal variation of the pulse length and/or the pulse ratio of the respective potentials is also possible.

Preferably, the plasma grid electrode is charged by a third potential U_{beam} whose polarity depends on the charge carriers to be extracted. In another embodiment, the plasma grid electrode is not charged with a defined potential so that the potential of the plasma grid electrode floats and is essentially determined by the potential of an additional plasma electrode in the charge carrier generation chamber.

If the electrode arrangement has, in the particle emission direction after the acceleration grid electrode, an electrically conductive ground grid electrode provided with corresponding openings, which comprises at least a first grid electrode region in a third layer, wherein the second layer and the third layer are spaced from each other by a second distance along the particle emission direction, the ground grid electrode is then preferably grounded.

If the device for extracting electrical charge carriers comprises several such electrode arrangements, then each of the plurality of electrode arrangements is controlled as described above so that the at least one particle beam emerging from the entire device for extracting electrical charge carriers has a desired beam characteristic.

According to the invention, one or more of the above-described devices for extracting electrical charge carriers are used for processing the surface of a substrate using one or more particle beams from at least one device for extracting electrical charge carriers such that the beam characteristics of the one or more particle beams from the at least one device for extracting electrical charge carriers are changed in a desired way by means of the method for operating the device for extracting electrical charge carriers according to the invention during the processing of the substrate as a function of a known property pattern of the substrate surface and of the method progress,. A property pattern of the substrate surface is understood to be the physical and/or chemical properties related to defined surface areas of the substrate surface as well as the surface topography, which have a distribution over the entire substrate surface caused by the production or a preceding processing of the substrate. The substrate surface is influenced by the impinging of the electrical charge carriers. Material can thereby be removed from or applied to the substrate surface, or the chemical or physical properties of the material of the substrate surface are altered so as to allow or prevent a reaction with other substances. It is also possible to influence hygroscopic, optical, crystallographic, electrical, magnetic or other physical properties.

Preferably, ions are used for processing the surface of a substrate so that the device for extracting electrical charge carriers is an ion beam source.

Preferably, in the method for processing the surface of a substrate, one or more devices for extracting electrical charge carriers are controlled in such a way that several particle beams impinge simultaneously on the substrate, wherein the plurality of particle beams have the same or different beam characteristics.

Preferably, one or more devices for extracting electrical charge carriers are controlled such that a plurality of particle beams impinge on a common area on the substrate surface, wherein the plurality of particle beams have different beam characteristics, and wherein the common area corresponds approximately to the incident area of the impinging particle beam which has the largest incident area of all incident particle beams. Thus, for example, the formation of structures with different heights or depths within a structure and/or with different or non-uniform shapes is possible in only one processing operation. In this case, the beam characteristics can differ with respect to the lateral extension or the pattern of the respective particle beam and/or with regard to the focus, the particle density, the particle type or other features.

### BRIEF DESCRIPTION OF THE DRAWINGS

In the following, the invention is illustrated by means of exemplary embodiments and figures.

They show:

FIG. 1 a schematic representation of a device (1) for extracting electrical charge carriers from a charge carrier generation chamber (2) with two electrode arrangements (1a, 1b) which is arranged in a particle beam source (3).

FIG. 2A a cross-section through an electrode arrangement (1a′) according to the prior art which has a plasma grid electrode (11′), a switching grid electrode (12′), an acceleration grid electrode (13′) and a ground grid electrode (14′).

FIG. 2B a plan view of the electrode arrangement (1a′) according to FIG. 2A.

FIG. 3 a cross-sectional view of an electrode arrangement (1a) according to the present invention, wherein first grid electrode regions (110a, 110b) of a first grid electrode (110) are configured in a first layer (100) and first grid electrode regions (210a, 210b) of a second grid electrode (210) are configured in a second layer (200). The first grid electrode regions (110a, 110b) form a first layer portion (101) of the first layer (100), in which additionally a second layer portion (102) is configured which is electrically insulated from the first layer portion (101) and is electrically conductively connected to the first grid electrode regions (210a, 210b) of the second grid electrode.

FIG. 4 a first design of a first embodiment of the electrode arrangement (1a) according to the invention in cross-section, in which the second layer portion (102) is configured by a second grid electrode region (210c) of the second grid electrode.

FIG. 5 a second design of the first embodiment of the electrode arrangement (1a) according to the invention in cross-section.

FIG. 6 a continuous course of the transition between the first grid electrode regions (210a, 210b) of the second grid electrode and the second grid electrode region (210c) of the second grid electrode in an exemplary design in cross-section.

FIG. 7 a third design of the first embodiment of the electrode arrangement (1a) according to the invention in cross-section.

FIG. 8 a second embodiment of the electrode arrangement (1a) according to the invention in cross-section, in which the second layer portion (102) is configured by a second grid electrode region (110c) of the first grid electrode.

FIGS. 9A to 9D different patterns of the second layer portion (102) within the first layer (100) in plan view.

FIG. 10 an embodiment of the electrode arrangement (1a) according to the invention with two further grid electrodes (401, 402) in cross-section.

FIG. 11 an embodiment of the electrode arrangement (1a) according to the invention, in which the individual layers are curved surfaces, so that the particle partial beams (8) are focused.

FIG. 12 an embodiment of the device (1) for extracting electrical charge carriers according to the invention having eight electrode arrangements (1a-1h) in plan view.

FIGS. 13A to 13C different switching states of an embodiment of the electrode arrangement (1a) according to the invention, in which the switching grid electrode (12) is the first grid electrode (110) and the acceleration grid electrode (13) is the second grid electrode (210).

FIG. 14 an arrangement for processing a surface of a substrate (9) with a particle beam (20) which has been generated with the aid of the device (1) for extracting electrical charge carriers according to the invention.

FIG. 15 an arrangement according to FIG. 14, in which a plurality of particle beams impinge simultaneously on the substrate surface.

FIG. 16 an arrangement according to FIG. 15, in which the plurality of particle beams impinge on a common area on the substrate surface.

### DETAILED DESCRIPTION OF THE PREFERRED EMBODIMENTS

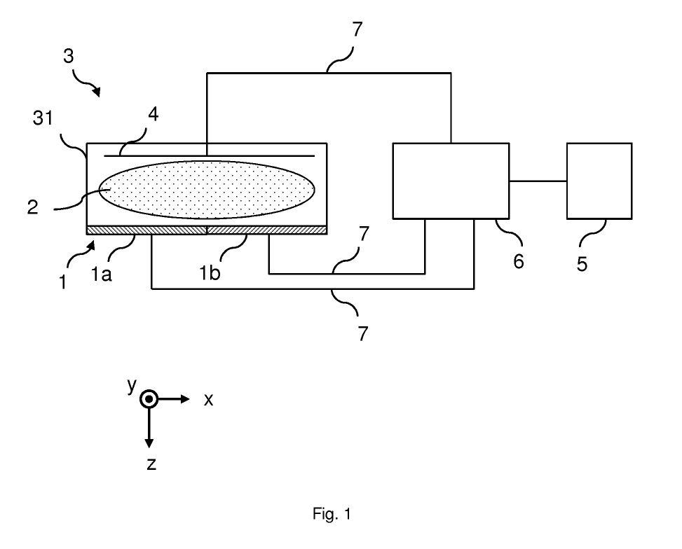

FIG. 1 schematically shows a device (1) for extracting electrical charge carriers from a charge carrier generation chamber (2). This charge carrier generation chamber (2) is, for example, a plasma that was generated within a housing (31) of a particle beam source (3) by means of one or more electrodes (4). Often, devices without electrodes are also used for plasma generation, such as, for example, inductively coupled plasma sources or microwave-assisted sources using the ECR effect. Hot filament sources can also be used. The plasma chamber, i.e., the chamber in which the plasma is generated, can, for example, be configured in the form of a pot or in the form of a pan or otherwise as known from the prior art. In addition, the charge carriers to be extracted can also be generated differently so that the charge carrier generation chamber (2) is not a plasma. For example, electron guns or ion guns can be used or targets can be atomized to generate ions. The specific configuration of the charge carrier generation chamber (2) is freely selectable as long as a sufficient supply of electrical charge carriers is present on the device (1) for extracting electrical charge carriers. The device (1) for extracting electrical charge carriers is arranged in or at the particle beam source (3) and comprises one or more electrode arrangements (1a, 1b). In this case, the one or more electrodes (4) for generating the charge carriers and the device (1) for extracting the charge carriers are charged with potentials by means of a device (5) for generating one or more electrical voltages via a switching device (6) and corresponding electrical lines (7).

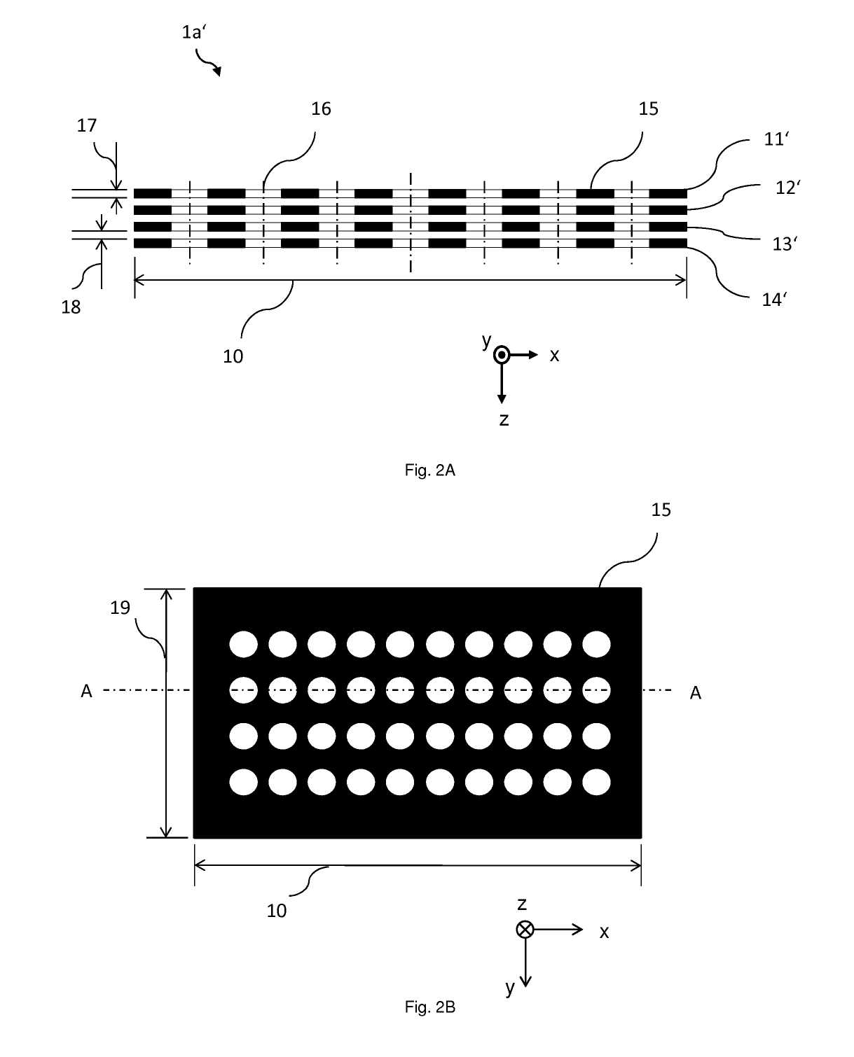

The electrode arrangements (1a, 1b) generally consist of one or more grid electrodes. FIG. 2A shows an electrode arrangement (1a′) according to the prior art in cross section, while FIG. 2B shows a grid electrode in the top view. (The line A-A in FIG. 2B marks the section line of the representation of FIG. 2A.) The electrode arrangement (1a′) according to the prior art has a plasma grid electrode (11′), a switching grid electrode (12′), an acceleration grid electrode (13′) and a ground grid electrode (14′). Each of these grid electrodes consists of an electrically conductive grid electrode material (15) and has openings (16) through which the extracted electrical charge carriers, hereinafter called particles, can pass through in the z-direction. The z-direction is thus the particle emission direction. That is, the openings (16) extend from a surface of the grid electrode to the opposing surface of the grid electrode, wherein the opening can run straight or oblique. Openings (16) corresponding to each other (aligned openings) in the different grid electrodes (11′, 12′, 13′, 14′) permit the passage of a specific particle beam in the z-direction. Metals, for example, molybdenum or tungsten, or graphite are used as the grid electrode material, wherein the grid electrode material can also be a layer sequence of several electrically conductive materials or else of an electrically non-conductive base body having a coating of an electrically conducting material. The openings (16) may have different circumferential geometries, for example, they can be round, elliptical or polygonal, may have different dimensions and/or can be distributed uniformly or non-uniformly over the lateral extension of the grid electrode in the x-y plane. The openings (16) have, for example, a hole diameter of 0.5 mm to 3 mm, while the grid electrode material (15) typically has a web width, i.e., a width between two adjacent openings (16), of 0.5 mm to 1 mm. The distribution of the openings (16) over the entire lateral extension of a grid electrode can be configured in such a way that a homogeneous distribution of the current density in the particle beam or in selected regions of the particle beam is achieved. In addition, with the density of the arrangement of openings (16), i.e., with the selection of the web width between adjacent openings (16), the achievable current density in a corresponding region of the particle beam can be adjusted. Thus, for example, a dense arrangement of openings (16), i.e., small web widths, a high current density is achieved.

Each grid electrode has a first lateral extension (10) in the x-direction, a second lateral extension (19) in the y-direction, and a thickness (17) in the z-direction, wherein the first lateral extension (10) and the second lateral extension (19) can be from a few millimeters up to several meters, and the thickness (17) can typically be 200 μm to 1 mm. However, if the grids have very large lateral extensions, it may also be necessary to use thicker grids, e.g. of a few millimeters in thickness. The grid electrodes can have an arbitrary circumferential geometry, which can be, for example, rectangular, round, elliptical or polygonal. Preferably, all the grid electrodes of an electrode arrangement are configured identically or have only slight differences in the parameters mentioned. The individual grid electrodes have a distance (18) with respect to one another, which is typically between 0.5 mm and 1.5 mm and is preferably equal between all grid electrodes. Said grid electrode parameters are chosen according to the mechanical, electrical and thermal strain of the grid electrodes. The grid electrodes are each configured in a layer which is either planar as shown in FIG. 2A, or has a radius of curvature, wherein however the distance between the individual grid electrodes always remains approximately the same. It is characteristic that each grid electrode is configured only in one layer and each layer is completely electrically insulated from the other layers.

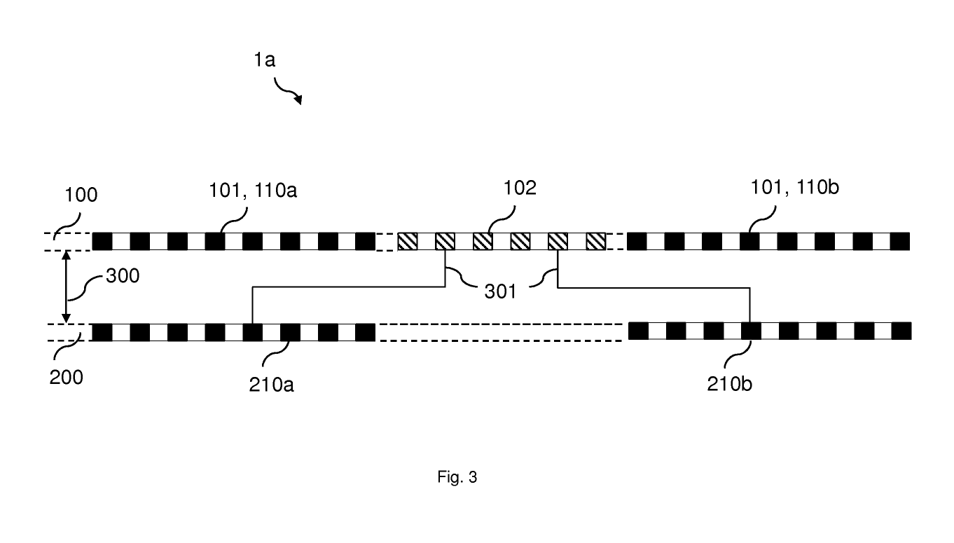

On the other hand, an electrode arrangement (1a) according to the invention, as shown in FIG. 3, is characterized by an electrically conductive connection between a grid electrode region, which forms a layer portion of a first layer, and a grid electrode region, which is configured in a second layer wherein the grid electrode region in the first layer is electrically insulated from other grid electrode regions in the first layer. FIG. 3 shows a schematic representation of this arrangement. A first layer (100) and a second layer (200) are shown, which are symbolized by dashed lines and each form a closed surface. The first layer (100) and the second layer (200) are spaced apart from each other by a first distance (300). A first grid electrode is arranged in the first layer (100), the first grid electrode having first grid electrode regions (110a, 110b). These grid electrode regions (110a, 110b) form the first layer portion (101) of the first layer (100). A second grid electrode is arranged in the second layer (200) and has first grid electrode regions (210a, 210b). In the first layer (100), a further grid electrode region (shown shaded) is additionally arranged, which forms a second layer portion (102) of the first layer (100) and which is electrically insulated from the first layer portion (101) of the first layer (100), but is electrically conductively connected to the first grid electrode regions (210a, 210b) of the second grid electrode in the second layer (200). This electrical connection is illustrated schematically by the lines with reference numeral 301, wherein the electrical connection (301) need not be an electrical line in the sense of a wire bridge or the like. All grid electrode regions which form layer portions of the first layer (100), that is, the first layer portion (101) and the second layer portion (102), have a grid electrode material and openings as described with reference to FIG. 2. The grid electrode regions arranged in the second layer (200) also comprise a grid electrode material and openings for the passage of charge carriers. In this case, mutually corresponding openings in the grid electrode regions of the first layer (100) and of the second layer (200) permit the passage of a specific particle beam through the first and the second layer along a straight line.

As can be seen in FIG. 3, the second layer portion (102) may be spaced from the perimeter of the first layer (100), i.e., is located inside the first layer (100). Nevertheless, via the electrical connection (301) to the first grid electrode regions (210a, 210b) of the second gird electrode, which adjoins the circumference of the second layer (200), a charging of the second layer portion (102) with an electrical potential, which is different from the electrical potential of the first layer portion (101), is possible via an electrical contact to the outer boundary, i.e., the circumference, of the electrode arrangement (1a).

In addition to the first grid electrode regions (210a, 210b) of the second grid electrode, further grid electrode regions of the second grid electrode or grid electrode regions of a further grid electrode may be configured in the second layer (200). It is also possible for the first grid electrode regions (210a, 210b) of the second grid electrode to extend continuously over the entire second layer (200). For a clear illustration of the basic idea according to the invention, FIG. 3 shows only the first grid electrode regions (210a, 210b) of the second grid electrode, while further regions in the second layer (200) have been omitted.

The design of the electrical connection (301) as well as of the first grid electrode and the second grid electrode is explained in the following with reference to some exemplary embodiments, wherein the representation of the openings (16) in the individual grid electrodes is dispensed with for the sake of clarity. Also, in each case, only one grid electrode region, which forms the second layer portion, is shown, wherein however the number of these grid electrode regions is not limited.

In a first embodiment of the electrode arrangement (1a) according to the invention, the first grid electrode has only the first grid electrode regions (110a, 110b) and thus does not form the entire first layer (100), while the second layer portion (102) Is formed by a second grid electrode region (210c) of the second grid electrode.

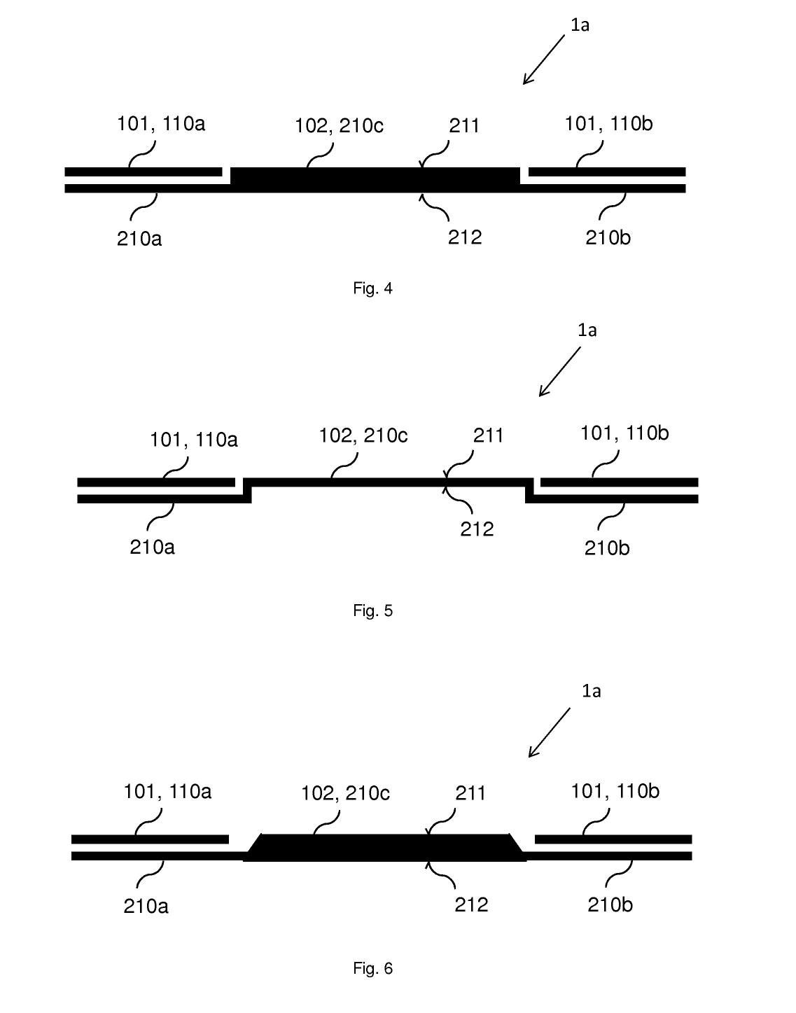

FIG. 4 shows a first design of this embodiment, wherein the second grid electrode region (210c) is thicker than the first grid electrode regions (210a, 210b) of the second grid electrode. Thus, a first surface (211) of the second grid electrode region (210c) is configured in the first layer (100) while a second surface (212) of the second grid electrode region (210c) is arranged in the second layer (200). The first surface (211) and the second surface (212) are located opposite one another. Thus, the second grid electrode “projects into” the first layer (100). The second grid electrode region (210c) is preferably configured as one piece with the first grid electrode regions (210a, 210b) of the second grid electrode and can be produced, for example, by means of an additive (selective deposition) or a subtractive (etching) process. Preferably, the geometry of the openings, for example, the hole diameter, is also changed in the second grid electrode region (210c) opposite that of the openings in the first grid electrode regions (210a, 210b) to compensate for the effects of the greater thickness of this region on the charge carriers passing through it. Alternatively or additionally, the openings in the second grid electrode region (210c) can also be arranged differently than in the first grid electrode regions (210a, 210b).

FIG. 5 shows a second design of the first embodiment, in which the second grid electrode region (210c) has the same thickness as the first grid electrode regions (210a, 210b) of the second grid electrode and is configured as one piece with it. Thus, the second grid electrode is “put over into” the first layer (100). This configuration can be achieved, for example, by a forming process of the second grid electrode, e.g., molds. Again, the geometry and/or the arrangement of the openings in the second grid electrode region (210c) can differ here from that in the first grid electrode regions (210a, 210b).

In both designs of the first embodiment, the transitions between the first grid electrode regions (210a, 210b) and the second grid electrode region (210c) can be configured continuous to avoid inhomogeneities in the electric field and the mechanical strain of the second grid electrode. This is illustrated by way of example for the first design in FIG. 6. The transition between the first surface (211) of the second grid electrode region (210c) to the surface of the first grid electrode regions (210a, 210b) in each case runs obliquely. Alternatively or additionally, the surfaces of the second grid electrode can be rounded at the transition points, so that a round “edge” is produced.

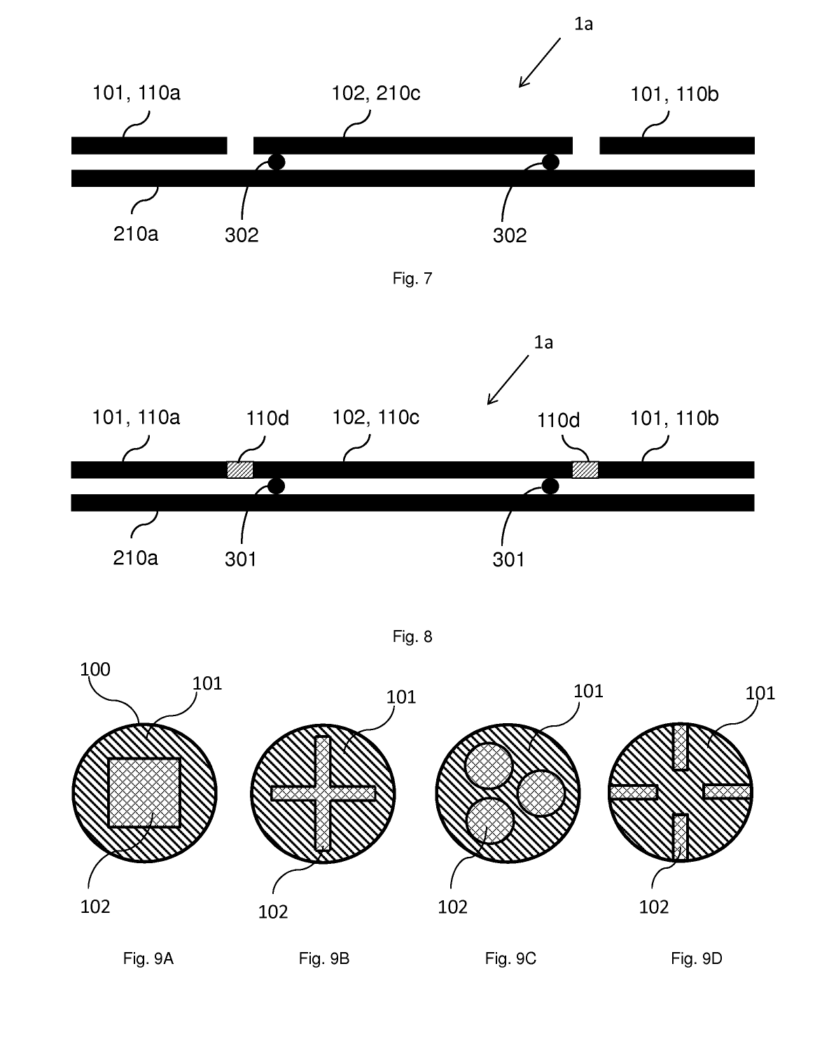

FIG. 7 shows a further design of the first embodiment, in which the second grid electrode region (210c) of the second grid electrode is not configured as one piece with the first grid electrode region (210a) of the second grid electrode. The first grid electrode region (210a) thereby completely maps the second layer (200), while the second grid electrode region (210c) is spaced apart from the first grid electrode region (210a) of the second grid electrode with the first distance (300) and is connected via at least one electrically conductive spacer (302) to the first grid electrode region (210a) of the second grid electrode. Such spacers (302) may, for example, be bumps, balls, cylinders or the like which ensure both the electrical connection and the mechanical stability of the arrangement of the second grid electrode region (210c) in the first layer (100). The second grid electrode region (210c) of the second grid electrode has no physical (mechanical) connection to the first grid electrode regions (110a, 110b) of the first grid electrode, except via the spacers (302). The second grid electrode region (210c) can be generated as an independent component, which is subsequently connected to the first grid electrode region (210a) by means of the spacers (302). However, it is also possible to produce the second grid electrode region (210c) together with the first grid electrode region (210a) of the second grid electrode or with the first grid electrode regions (110a, 110b) of the first grid electrode and to generate a physical or mechanical “separation” later.

In a second embodiment of the electrode arrangement (1a) according to the invention, the first grid electrode has, in addition to the first grid electrode regions (110a, 110b), a second grid electrode region (110c) which is physically (mechanically) connected to the first grid electrode regions (110a, 110b) and forms the second layer portion (102) of the first layer (100). Thus, the first grid electrode forms the entire first layer (100). This is illustrated in FIG. 8. The second grid electrode region (110c) of the first grid electrode is electrically insulated from the first grid electrode regions (110a, 110b) by electrically insulating grid electrode regions (110d) and is electrically conductive connected to the first grid electrode region (210a) of the second grid electrode, which completely fills the second layer (200), via at least one electrically conductive connection (301). These electrically conductive connections (301) can again be the spacers already described with reference to FIG. 7, which however do not have to guarantee the mechanical stability of the arrangement in this embodiment, since the mechanical stability is already provided by the electrically insulating grid electrode regions (110d) of the first grid electrode.

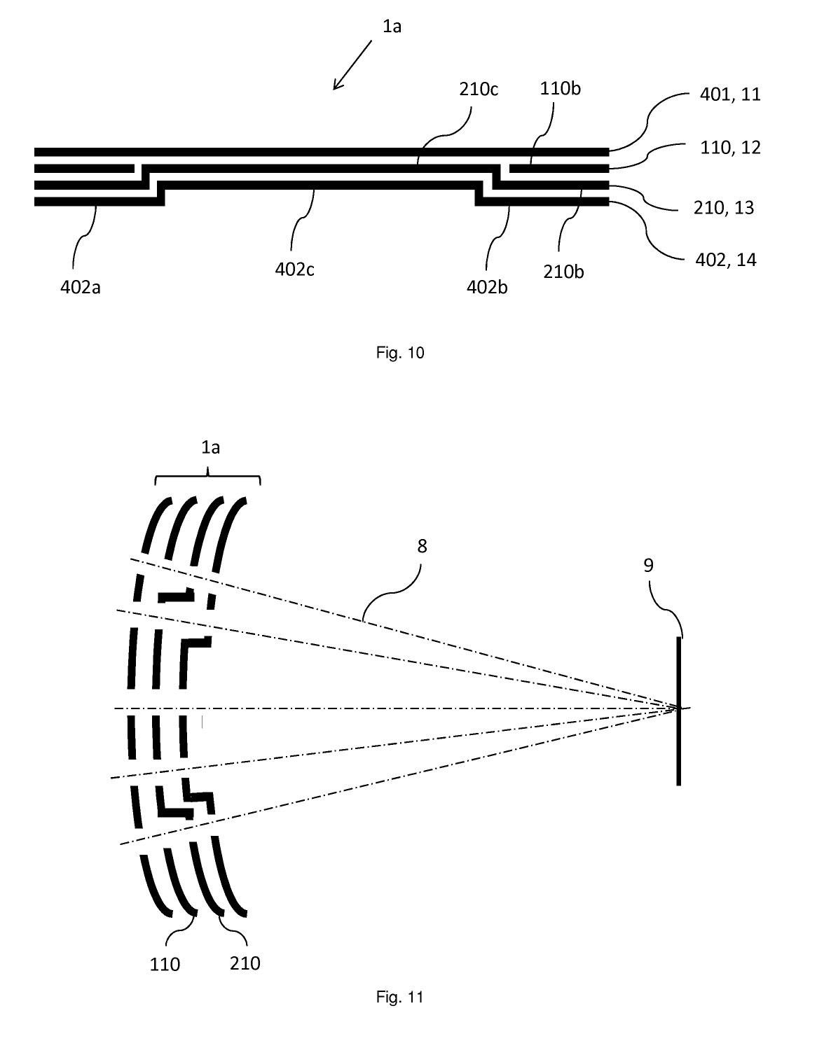

As already mentioned, the second layer portion (102) can be configured by a coherent grid electrode region. This is illustrated in FIGS. 9A and 9B, which show the first layer (100) with the first layer portion (101) and the second layer portion (102). The electrical insulation by a physical distance or an electrically insulating intermediate region between the two layer portions is not shown here.

FIGS. 9C and 9D show other examples in which the second layer portion (102) is configured by a plurality of grid electrode regions spaced from each other. In FIG. 9C, three round grid electrode regions form the second layer portion (102), while in FIG. 9D, four rectangular grid electrode regions form the second layer portion (102). In the illustrated examples, the grid electrode regions of the second layer portion (102) are all uniformly formed with respect to their circumferential geometry and arranged uniformly within the first layer (100), for example, with respect to a center point of the first layer (100). However, this is not necessary, so that the individual grid electrode regions can also be configured differently in terms of their circumferential geometry and/or their arrangement within the first layer (100). FIG. 9D also shows that the grid electrode regions which form the second layer portion (102) can also adjoin the circumference of the first layer (100).

The circumferential geometry of the first layer (100) and of the grid electrode regions, which form the second layer portion (102), is not limited to the illustrated geometries. Also, another arrangement of the grid electrode regions which form the second layer portion (102) is possible within the first layer (100). The circumferential geometries and dimensions of the grid electrode regions which form the second layer portion (102) and their arrangement within the first layer (100) represent a pattern of the electrode arrangement (1a).

In addition to the first grid electrode and the second grid electrode, the electrode arrangement may also have further grid electrodes which are likewise electrically conductive and have corresponding openings. FIG. 10 illustrates by example two further grid electrodes, so that the electrode arrangement (1a) consists of four grid electrodes. In the illustrated case, these are the first grid electrode (110) which implements a switching grid electrode (12), the second grid electrode (210), which shows an acceleration grid electrode (13), and two further grid electrodes ( 401, 402), which are used as a plasma grid electrode (11) and a ground grid electrode (14). In other exemplary embodiments, the grid electrodes can also be arranged differently, wherein the functionalities of the grid electrodes are then also differently assigned. For example, it is also possible that the first grid electrode (110) is the switching grid electrode and the plasma grid electrode realizes the second grid electrode (210). However, the grid electrodes in the particle emission direction, i.e., away from the charge generating chamber, are always arranged in the following order: Plasma grid electrode (11), switching grid electrode (12), acceleration grid electrode (13) and ground grid electrode (14). In this case, further grid electrodes can be arranged, for example, between the plasma grid electrode (11) and the switching grid electrode (12), or between the acceleration grid electrode (13) and the ground grid electrode (14), but not between the grid electrodes which form the first grid electrode and the second grid electrode.

The further grid electrodes (401, 402) each comprise at least one first grid electrode region, which is arranged in a further layer, wherein the further layer and the layer adjacent to it are spaced from each other by a further distance along the particle emission direction. As shown in FIG. 10, the plasma grid electrode (11) is arranged in a third layer spaced by a second distance from the first layer, wherein the plasma grid electrode (11) has only grid electrode regions in the third layer in the illustrated case. The plasma grid electrode (11) is thus configured uniformly and has no “bulges” or other irregularities which, for example, can adversely affect a plasma.

When the second grid electrode (210), in the illustrated case the acceleration grid electrode (13), is formed according to the second design of the first embodiment of the electrode arrangement (1a), as illustrated in FIG. 5, and is thus configured to be “put over” into the first layer, one (or more) of the further grid electrodes, which are arranged on the side of the second grid electrode (210) facing away from the first grid electrode (110), have second grid electrode regions which are arranged in the second layer. In other words: Further grid electrodes can then also be put over into the respective adjacent layer. This is shown by example in FIG. 10 for the ground grid electrode (14), which has first grid electrode regions (402a, 402b) and a second grid electrode region (402c). The first grid electrode regions (402a, 402b) are arranged in a fourth layer which is spaced by a third distance from the second layer, while the second grid electrode region (402c) is arranged in the second layer. Advantageously, the distances between regions with different potential, for example, between the acceleration grid electrode (13) and the ground grid electrode (14), are equal over the entire extension of the grid electrodes concerned, so that a uniform particle beam is produced.

FIG. 11 shows an example of an electrode arrangement (1a), in which the individual layers are not planar, but curved surfaces so that the individual particle beams (8) passing through the openings in the grid electrodes are focused so that they are all concentrated impinging in a common impact surface on a substrate (9). The electrode arrangement (la) again has the grid electrodes described with reference to FIG. 10, wherein the first grid electrode (110) and the second grid electrode (210) are configured as in the design described with reference to FIG. 5. An adaptation of the circumferential geometries, the dimensions and/or the arrangement of the openings in the individual grid electrodes is advantageous in order to compensate the design of the layers as curved surfaces, i.e., as surfaces with an embossed, finite radius.

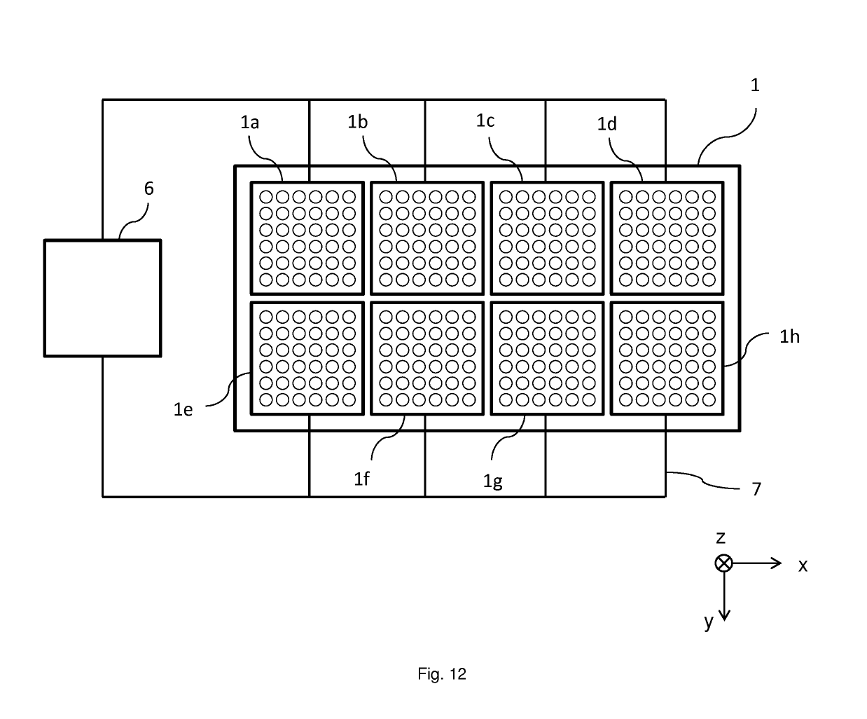

FIG. 12 shows an embodiment of the device (1) for extracting charge carriers according to the invention having a plurality of electrode arrangements (1a-1h) in plan view. In this case, the electrode arrangements (1a-1h) are arranged in a 4×2 matrix, i.e., four electrode arrangements (1a-1d and 1e-1h) are arranged in two rows respectively. Thus, along a first lateral extension of the device (1), i.e., along the x-direction, four electrode arrangements (1a-1d and 1e-1h, respectively) are arranged adjacent to one another, while along a second lateral extension of the device (1), i.e., along the y-direction, only two electrode arrangements are arranged adjacent to one another. Thus, all electrode arrangements (1a-1h) are electrically contactable from the outer circumference of the device (1), so that they can be charged with one or more electrical potentials via the switching device (6) or several switching devices and the corresponding electrical lines (7). In the illustrated case, all the electrode arrangements (1a-1h) have the same pattern of the layer portions of the first layer, wherein however, one or more or all electrode arrangements may also have different patterns. As illustrated, the electrode arrangements (1a-1h) map almost the entire lateral extension of the device (1), wherein only edge regions as well as intermediate regions between the individual electrode arrangements (1a-1h) are not covered.

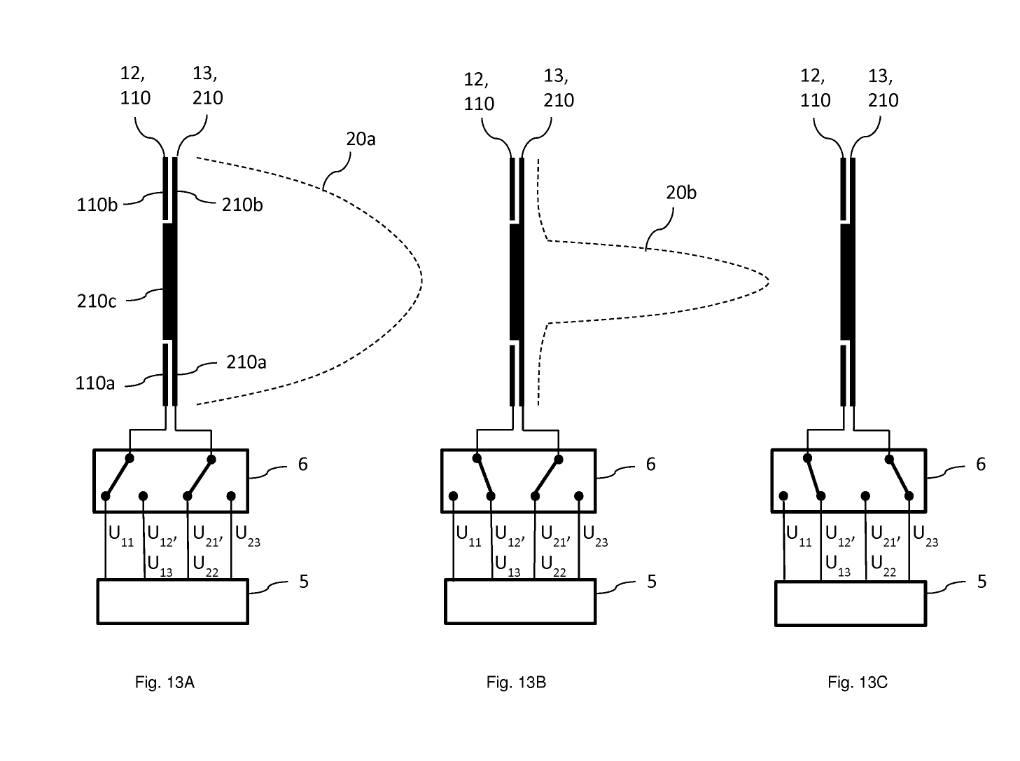

With reference to FIGS. 13A to 13C, it is by way of example explained with respect to an exemplary embodiment how the device (1) according to the invention is operated so that a desired beam characteristic of the particle beam passing through at least one electrode arrangement (1a) is generated. In the exemplary embodiment, the circuitry of an electrode arrangement is shown, the electrode arrangement having a switching grid electrode (12) which acts as a first grid electrode (110) and an acceleration grid electrode (13) which acts as a second grid electrode (210), wherein the acceleration grid electrode (13) is arranged past the switching grid electrode (12) in the particle emission direction. The first grid electrode (110) and the second grid electrode (210) are configured, for example, as in the first design of the first embodiment shown in FIG. 4. The first grid electrode (110) and the second grid electrode (210) are connected via a switching device (6) to a device (5) for generating electrical voltages which can provide at least two different values for a first potential of the first grid electrode regions (110a, 110b) of the first grid electrode (110) and at least two different values for a second potential of the first grid electrode regions (210a, 210b) of the second grid electrode (210) and of the second grid electrode region (210c) of the second grid electrode (210) that is electrically conductively connected with the first grid electrode regions of the second grid electrode. Several switching devices (6) and/or several devices (5) can also be used to generate electrical voltages.

In a first switching state, shown in FIG. 13A, the first potential has a first value U₁₁ and the second potential has a second value U_{21,} wherein the values are suitable for extracting charge carriers from the charge generation chamber. That is, the first value U₁₁ and the second value U₂₁ are, for positive charge carriers, smaller (more negative) than the value of the potential in the charge carrier generation chamber or the potential of a plasma grid electrode (referred to as U_{beam} in the following), while it is reversed for negative charge carriers. In this case, the magnitude of the second value U₂₁ can differ, for example, by a maximum of ±10% from the magnitude of the first value U₁₁. However, larger differences are also possible as long as the first and the second potential allow the passage of charge carriers through all grid electrode regions. Since the potentials of the first grid electrode regions (110a, 110b) of the first grid electrode (110) and of the first grid electrode regions (210a, 210b) and of the second grid electrode region (210c) of the second grid electrode (210) are both suitable for extracting charge carriers, the entire lateral extension of the electrode arrangement is thus used for extracting charge carriers. This results in a total beam (20a) which has a large lateral extension. For example, such a focused ion beam for an exemplary electrode arrangement having a grid electrode diameter of 40 mm can have an impingement diameter of approximately 4.5 mm on a substrate surface to be processed. “Grid electrode diameter” is understood here to mean the diameter of a circular region of the electrode arrangement in relation to a layer in which grid electrode regions are configured. The grid electrode regions have the above-described openings, while the individual grid electrodes can also have edge regions, for example, for physically fastening the grid electrode in a housing or in another device or for applying a potential to the grid electrode, in which edge regions no openings are configured. Thus, both the lateral dimensions of the electrode arrangement and the circumferential geometry of the electrode arrangement can be different from this region.

In a second switching state, shown in FIG. 13B, the first potential has a third value U_{12,} while the second potential has a fourth value U_{22.} In this case, the third value U₁₂ is suitable for preventing or strongly restricting the extraction of charge carriers from the charge carrier generation chamber. In other words: For positive charge carriers, the third value U₁₂ is greater (more positive) than the value of the potential in the charge carrier generation chamber or than U_{beam}, while it is reversed for negative charge carriers. The fourth value U_{22,} on the other hand, is suitable for extracting charge carriers, wherein the fourth value U₂₂ is equal to the second value U_{21,} as shown in FIG. 13B. However, the fourth value U₂₂ may also be different from the second value U₂₁ to compensate for the altered electrical ambient conditions. Thus, only the second grid electrode region (210c) of the second grid electrode (210), which forms the second layer portion of the first layer and is electrically conductively connected to the first grid electrode regions (210a, 210b) of the second grid electrode (210), contributes to extracting charge carriers, while the first grid electrode regions (210a, 201b) of the second grid electrode (210) are shielded by the first grid electrode regions (110a, 110b) of the first grid electrode (110). Therefore, the partial beam (20b) maps only the geometry of the second layer portions of the first layer and has dimensions which are smaller than that of the total beam (20a). In the illustrated example, a partial beam (20b) with a smaller diameter of, for example, approximately 2 mm, is generated, wherein the diameter of the second grid region (210c) of the second grid electrode (210), i.e., the diameter of the second layer portion of the first layer, is 10 mm.

In a third switching state, shown in FIG. 13C, the first potential has a fifth value U₁₃ and the second potential has a sixth value U_{23,} wherein the fifth value U₁₃ and the sixth value U₂₃ are suitable to prevent or severely restrict the extraction of charge carriers from the charge carrier generation chamber. The fifth value U₁₃ and the sixth value U₂₃ are thus greater (more positive) than the value of the potential in the charge carrier generation chamber or than U_{beam} for positive charge carriers, while it is reversed for negative charge carriers. The fifth value U₁₃ may be equal to the third value U_{12,} as shown in FIG. 13C. However, the fifth value U₁₃ can also be different from the third value U₁₂ in order to compensate for the changed electrical ambient conditions. Moreover, the sixth value U₂₃ may be equal to or nearly equal to or different from the fifth value U_{13.} Since now all the layer portions of the first layer are at a potential which prevents the extraction of charge carriers, no particle beam is generated.

The following table lists sample values for the potential of a plasma grid as well as for transmitting or blocking values of the first and second potential for positive charge carriers:

| U_{beam} | U₁₁ | U₁₂, U₁₃ | U₂₁, U₂₂ | U₂₃ |
|---|---|---|---|---|
| 700 V | −100 V | 800 . . . 900 V | −100 V | 800 . . . 900 V |

In addition, further switching states with further values of the first or the second potential can also be provided. Thus, particle beams which have shapes other than those shown here can also be generated, for example, a particle beam which extends over the entire lateral extension of the electrode arrangement but has a different particle density or particle energy in the region of the first layer portion than in the region of the second layer portion.

The first and/or the second potential can also be charged in a pulsed manner, wherein the pulse duration as well as the pulse ratio can be the same or different from one another and/or over time.

The plasma grid can be charged with a third potential U_{beam} as shown above or can float.

If the electrode arrangement further has a ground grid electrode past the acceleration grid, then this is preferably grounded.

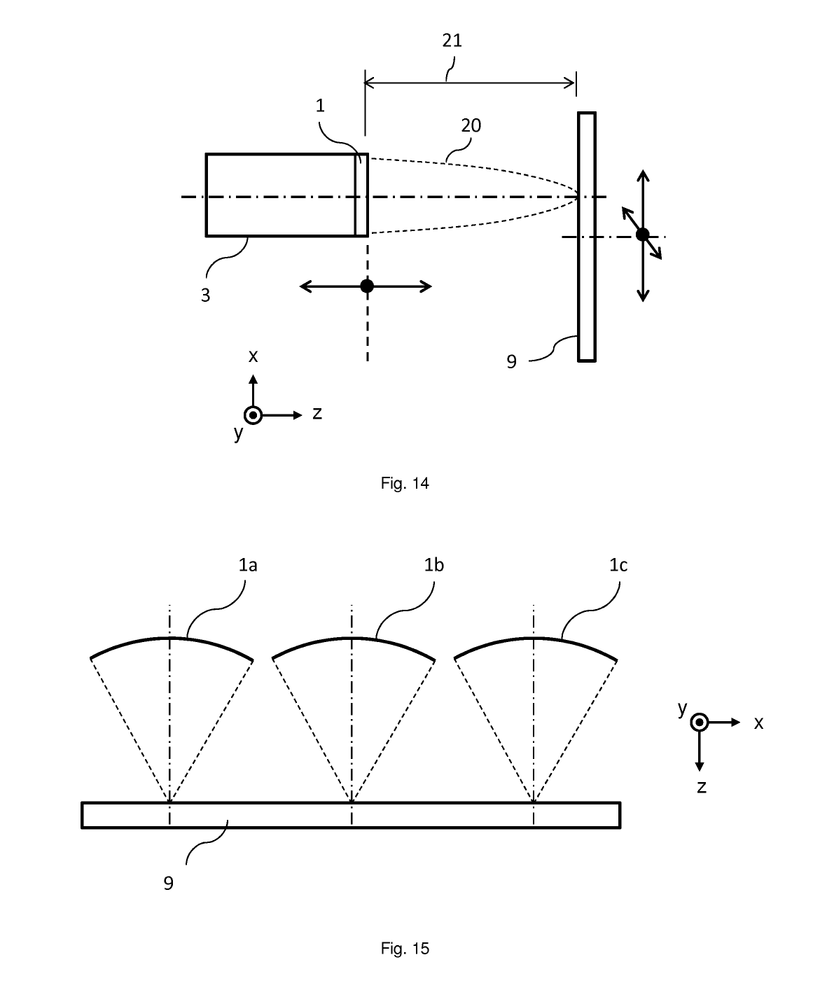

With reference to FIGS. 14 to 16, a method for processing a surface of a substrate (9) using one or more particle beams from at least one device (1) according to the invention is explained in the following.

FIG. 14 shows a particle beam source (3) which comprises the device (1) for extracting electrical charge carriers according to the invention and generates a particle beam (20) which impinges on the surface of a substrate (9) and processes it. In this case, the particle beam source (3) and the substrate surface are arranged with a distance (21) along the z-direction, i.e., along the particle emission direction, the distance (21) being variable by a movement of the particle beam source (3) and/or of the substrate (9) along the z-direction. In addition, the particle beam source (3) and/or the substrate (9) can be laterally moved, i.e., in the x-direction and/or y-direction, tilted to the z-direction and/or to the x-y-plane and/or rotated about an axis which runs parallel to the z-direction. All movements can be executed uniformly or non-uniformly. During processing of the substrate surface, the beam characteristics of the particle beam (20) are controlled as a function of a known property pattern of the substrate surface and of the method progress by means of the above-described method for controlling the beam characteristics (FIGS. 13A to 13C) such that a desired property pattern of the substrate surface is obtained after the processing is finished. For example, the substrate surface can be processed in large-area regions having a homogeneous property pattern with a particle beam having a large lateral extension, for example, the total beam (20a) from FIG. 13A, while for processing smaller regions having a homogeneous property pattern, a particle beam having a smaller lateral extension can be used, for example, the partial beam (20b) from FIG. 13B. The desired processing quality or processing quantity in a certain region of the substrate surface may also be decisive for the selection of a specific beam characteristic.

If several particle beams from one or more devices (1) for extracting electrical charge carriers according to the invention are used for processing the substrate surface, the substrate surface can then simultaneously be processed in a plurality of lateral regions of the substrate surface. This is shown schematically in FIG. 15, wherein, for example, three electrode arrangements (1a-1c) of a device (1) for extracting electrical charge carriers are shown. However, the electrode arrangements (1a-1c) can also be contained in one of a plurality of devices (1) for extracting charge carriers, wherein a specific device (1) for extracting electrical charge carriers is respectively contained in a specific particle beam source. Thus, for example, identical or different methods which use different particles or different beam characteristics for processing can be carried out simultaneously.

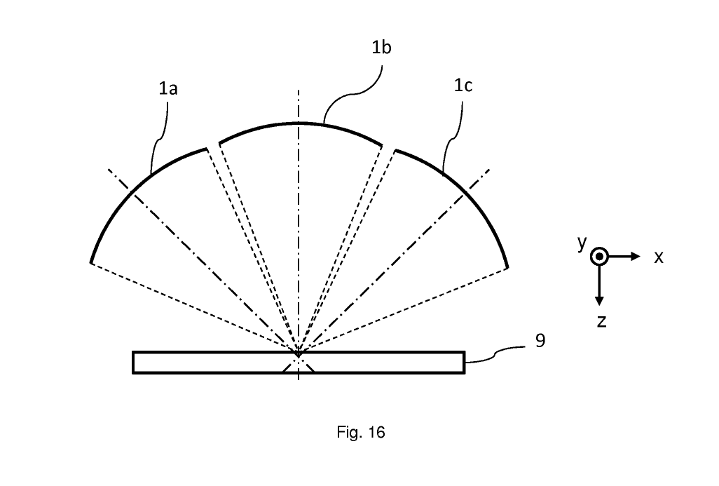

FIG. 16 shows a further embodiment of the method for processing a substrate surface, in which the particle beams generated by means of the electrode arrangements (1a-1c) of one or more devices (1) for extracting electrical charge carriers impinge on a common area on the substrate surface. That is, the particle beams are aligned on one and the same surface area, wherein the common area is determined by the impact area of that particle beam having the greatest lateral extension in the plane of the substrate surface. The different particle beams have different lateral dimensions and can have different shapes, foci, particle densities, particle energies and/or particle types. For example, structures having different etching depths can thus be created in the substrate surface with a common etching step by combining, for example, a particle beam with a small lateral extension and a particle beam with a large lateral extension. There, where both particle beams are impinging, a high removal rate and thus a large etching depth is achieved, while in regions in which only the particle beam with the large lateral extension impinges, only a small removal rate and thus a low etching depth is achieved.

All designs and embodiments of the device (1) for extracting electrical charge carriers according to the invention as well as of the methods for operating the device (1) for the extraction of electrical charge carriers and for processing a substrate surface according to the invention can be combined with one another and interchangeably, as long as this is not explicitly excluded or impossible for physical and/or technical reasons.

### LIST OF REFERENCE NUMERALS

1 Device for extracting electrical charge carriers
1a-1h Electrode arrangement according to the invention
1a′Electrode arrangement according to the prior art
2 Charge carrier generation chamber
3 Particle beam source
31 Housing of the particle beam source
4 Electrode(s)
5 Device for generating one or more electrical voltages
6 Switching device
7 Electrical line
8 Particle partial beam
9 Substrate
10 Lateral extension of the electrode arrangement in the x-direction
11 Plasma grid electrode according to the invention
11 Plasma grid electrode according to the prior art
12 Switching grid electrode according to the invention
12′ Switching grid electrode according to the prior art
13 Acceleration grid electrode according to the invention
13′ Acceleration grid electrode according to the prior art
14 Ground grid electrode according to the invention
14′ Ground grid electrode according to the prior art
15 Grid electrode material
16 Opening in a grid electrode
17 Thickness of a grid electrode
18 Distance between two grid electrodes
19 Lateral extension of the electrode arrangement in y-direction
20 Particle beam
20a Total beam
20b Partial beam
21 Distance of the device for extracting electrical charge carriers to the substrate surface
100 First layer
101 First layer portion of the first layer
102 Second layer portion of the first layer
110 First grid electrode
110a, First grid electrode region of the first grid electrode
110b
110c Second grid electrode region of the first grid electrode
110d Electrically insulating grid electrode region of the first grid electrode
200 Second layer
210 Second grid electrode
210a, First grid electrode region of the second grid electrode
210b
210c Second grid electrode region of the second grid electrode
211 First surface of the second grid electrode region of the second grid electrode
212 Second surface of the second grid electrode region of the second grid electrode
300 First distance (distance between first and second layer)
301 Electrically conducting connection between the second layer portion of the first layer and the first grid electrode regions of the second grid electrode
302 Electrically conductive spacer
401, 402 Other grid electrodes
401a, First grid electrode region of the further grid electrode
402a
402c Second grid electrode region of the further grid electrode

1. A device for extracting electrical charge carriers from a charge carrier generation chamber with at least one electrode arrangement for extracting charge carriers, wherein the at least one electrode arrangement has at least a first grid electrode and a second grid electrode having corresponding openings, each of the first and the second grid electrode containing at least one first electrically conductive grid electrode region, wherein the at least one first grid electrode region of the first grid electrode is configured in a first layer and the at least one first grid electrode region of the second grid electrode is configured in a second layer, wherein the first layer and the second layer are arranged within the electrode arrangement successively in the particle emission direction and are spaced from each other by a first distance along the particle emission direction, wherein the at least one first grid electrode region of the first grid electrode forms a first electrically conductive layer portion in the first layer, and a second electrically conductive layer portion is configured in the first layer, wherein the first layer portion and the second layer portion are electrically insulated from each other, characterized in that the second layer portion is formed by at least one second electrically conductive grid electrode region of the first grid electrode or of the second grid electrode and the second layer portion is electrically conductively connected to the at least one first grid electrode region of the second grid electrode.

2. The device according to claim 1, characterized in that the at least one first grid electrode region of the first grid electrode and the at least one first grid electrode region of the second grid electrode are arranged within the respective grid electrode so that they each adjoin the outer lateral periphery of the respective grid electrode.

3. The device according to claim 1, characterized in that the first grid electrode comprises only the at least one first grid electrode region and the second grid electrode comprises at least one second grid electrode region which forms the second layer portion of the first layer.

4. The device according to claim 3, characterized in that the at least one second grid electrode region of the second grid electrode is configured so thick that a first surface of the at least one second grid electrode region is located in the first layer and a second surface of the at least one second grid electrode region, which is opposite to the first surface, is located in the second layer.

5. The device according to claim 3, characterized in that the at least one second grid electrode region of the second grid electrode has the same thickness as the at least one first grid electrode region of the second grid electrode.

6. The device according to claim 3, characterized in that the transitions between the at least one first grid electrode region of the second grid electrode and the at least one second grid electrode region of the second grid electrode run continuously on both surfaces of the second grid electrode.

7. The device according to claim 3, characterized in that the at least one first grid electrode region of the second grid electrode completely maps the second layer and the at least one second grid electrode region of the second grid electrode is at least spaced apart from the at least one first grid electrode region of the second grid electrode in some lateral sections of the second grid electrode region.

8. The device according to claim 1, characterized in that the first grid electrode further comprises at least one second grid electrode region, which forms the second layer portion of the first layer.

9. The device according to claim 1, characterized in that the openings for the charge carrier passage in at least one second grid electrode region of the first grid electrode or of the second grid electrode are equal to or different from the openings for the charge carrier passage in at least a first grid electrode region of the second grid electrode with respect to their lateral extension and/or their circumferential geometry.

10. The device according to claim 1, characterized in that the second layer portion is formed by a coherent second grid electrode region of the first grid electrode or of the second grid electrode.

11. The device according to claim 1, characterized in that the second layer portion is formed by a plurality of second grid electrode regions of the first grid electrode or of the second grid electrode that are spaced from each other, wherein the plurality of second grid electrode regions that are spaced from each other have the same or different circumferential geometries and are distributed uniformly or non-uniformly over the lateral extension of the first layer.

12. The device according to claim 1, characterized in that the at least one electrode arrangement has at least one further, electrically conductive grid electrode provided with corresponding openings, which comprises at least one first grid electrode region in a further layer, wherein the further layer and the layer adjacent to it are spaced from each other by a further distance along the particle emission direction.

13. The device according to claim 1, characterized in that a further grid electrode is arranged adjacent to the second grid electrode on the side of the second grid electrode facing away from the first grid electrode, and this further grid electrode further has at least one second grid electrode region which is arranged in the second layer and is connected electrically conductively to the at least one first grid electrode region of this further grid electrode, wherein the lateral arrangement of the at least one second grid electrode region of this further grid electrode within the second layer corresponds to the lateral arrangement of the at least one second grid electrode region of the second grid electrode within the first layer.

14. The device according to claim 1, characterized in that one, several or all of the grid electrodes contained in the electrode arrangement are arranged individually detachable from a holder of the electrode arrangement or from one of the other grid electrodes.

15. The device according to claim 1, characterized in that the device has a plurality of electrode arrangements for extracting electrical charge carriers, wherein several electrode arrangements are arranged side by side in a first direction along the lateral extension of the device and at most two electrode arrangements are arranged side by side in a second direction along the lateral extension of the device so that the plurality of electrode arrangements cover almost the entire lateral extension of the device, and wherein the plurality of electrode arrangements have the same or different patterns of the second layer portions.

16. The device according to claim 1, characterized in that the at least one electrode arrangement successively comprises a plasma grid electrode, a switching grid electrode and an acceleration grid electrode in the particle emission direction, wherein the switching grid electrode is the first grid electrode and the plasma grid electrode or the acceleration grid electrode is the second grid electrode.

17. A method for operating a device according to claim 16, characterized in that, depending on a desired beam characteristic of the particle beam passing through one of the at least one electrode arrangement, each of the at least one electrode arrangement is controlled with the aid of a device for generating one or more electrical voltages and a switching device, so that the at least one first grid electrode region of the switching grid electrode of the specific electrode arrangement is charged with a first potential and the acceleration grid electrode of the specific electrode arrangement is charged with a second potential, wherein:
in a first switching state, the first potential has a first value U₁₁ and the second potential has a second value U_{21,} both of which are suitable for enabling the passage of charge carriers through the corresponding grid electrode regions.
in a second switching state, the first potential has a third value U₁₂ and the second potential has a fourth value U_{22,} wherein the third value U₁₂ is suitable for preventing the passage of charge carriers through the grid electrode regions of the switching grid electrode and of the acceleration grid electrode corresponding to the first layer portion, while the fourth value U₂₂ is suitable to allow the passage of charge carriers through the grid electrode regions of the switching grid electrode and of the acceleration grid electrode corresponding to the second layer portion, and
in a third switching state, the first potential has a fifth value U₁₃ and the second potential has a sixth value U_{23,} both of which are suitable for preventing the passage of charge carriers through the corresponding grid electrode regions.

18. The method according to claim 17, characterized in that the first potential and/or the second potential are applied in a pulsed manner.

19. The method according to claim 17, characterized in that the plasma grid electrode is charged with a third potential U_{beam}.

20. The method according to claim 17, characterized in that the electrode arrangement has, in the particle emission direction, past the acceleration grid electrode, an electrically conductive ground grid electrode provided with corresponding openings, which comprises at least one first grid electrode region in a third layer, wherein the second layer and the third layer are spaced from each other by a second distance along the particle emission direction, and the ground grid electrode is grounded.

21. A method for processing the surface of a substrate using one or more particle beams from at least one device according to claim 1, characterized in that, during the processing of the substrate, the beam characteristic of the one or more particle beams from the at least one device for extracting electrical charge carriers from a charge carrier generation chamber is changed in a defined manner as a function of a known property pattern of the substrate surface and of the method progress with the aid of the method according to one of claims 17 to 20.

22. The method according to claim 21, characterized in that a plurality of particle beams from at least one device for extracting electrical charge carriers from a charge carrier generation chamber impinge simultaneously on the substrate, wherein the plurality of particle beams have the same or different beam characteristics.

23. The method according to claim 22, characterized in that a plurality of particle beams impinge on a common area on the substrate surface, wherein the plurality of particle beams have different beam characteristics, and wherein the common area approximately corresponds to the impingement area of the impinging particle beam which has the largest impingement area of all impinging particle beams.
